(19) United States
(12) Patent Application Publication
(10) Pub. No.: US 2017/0110204 A1
(43) Pub. Date: Apr. 20, 2017

(54) ENHANCED MEMORY BUILT-IN SELF-TEST ARCHITECTURE FOR DE-FEATURED MEMORIES

(71) Applicant: QUALCOMM Incorporated, San Diego, CA (US)

(72) Inventors: Abhinav Kothiala, Ithaca, NY (US); Nishi Bhushan Singh, Bangalore (IN); Rajesh Tiwari, Bangalore (IN); Anand Bhat, Bangalore (IN); Ashutosh Anand, Banglaore (IN); Shankarnarayan Bhat, Bangalore (IN)

(21) Appl. No.: 14/885,840

(22) Filed: Oct. 16, 2015

(51) Int. Cl. G11C 29/38; G11C 29/44

(52) U.S. Cl. CPC G11C 29/38; G11C 29/44

(57) ABSTRACT

A method and apparatus for testing a device memory. The method begins with a generated data and address width from an automatic testing system. The generated data width and the generated address width is compared with the required data width and address width of a device under test and used to set a user bit. If the generated data width and address width match the required data and address width, the user bit is set to zero. If the generated data width and address width do not match the required data width and address width, the user bit is set to 1. The user bit provides address control and data control during testing. The apparatus includes a wireless test access protocol that is electrically connected to a glue logic module. A wireless test access port is electrically connected to the glue logic module as is the device under test.

### BACKGROUND

Field

The present disclosure relates generally to wireless communication system. More specifically the present disclosure related to methods and apparatus for an enhanced architecture for testing de-featured memories using a memory built-in self-test (MBIST) system.

Background

Wireless communication devices have become smaller and more powerful as well as more capable. Increasingly users rely on wireless communication devices for mobile phone use as well as email and Internet access. At the same time, devices have become smaller in size. Devices such as cellular telephones, personal digital assistants (PDAs), laptop computers, and other similar devices provide reliable service with expanded coverage areas. Such devices may be referred to as mobile stations, stations, access terminals, user terminals, subscriber units, user equipments, and similar terms.

These wireless communication devices typically use a system-on-chip (SoC) to provide many of the functions of the device. A SoC is an integrated circuit that combines all components of a computer or other electronic system on a single chip. The SoC device may contain digital, analog, mixed-signal, and radio frequency (RF) functions on a single substrate. SoCs are used widely due to their low power consumption.

A typical SoC consists of a microcontroller or digital signal processor (DSP) core, memory blocks including a selection of ROM, RAM, EEPROM, and flash memory, as well as timing sources. The timing sources may include oscillators and phase-locked loops (PLL). Peripherals, including counter-timers, real-time timers, and power-on reset generators may also be incorporated. A wide variety of external and internal interfaces including analog-to-digital (ADC), digital-to-analog converters (DAC), voltage regulators and power management circuits are also typically included in an SoC. The desired performance of the end device may result in different mixes of the above functions to be included in the SoC. The SoC also includes a bus system for connecting the various functional blocks.

Testing an SoC may be complex and time consuming Memory functionality may be tested using memory built-in self-testing (MBIST). This memory testing typically utilizes testing programs that automatically test the flow of data into and out of the various memories on the SoC. In some cases, the SoC may be de-featured, that is, have the memory size reduced. This memory de-featuring results in a smaller memory and may complicate the testing process, as the MBIST testing program may not be able to take into account the reduction in memory size. The de-featuring may result in MBIST testing that cannot be completed without a complete re-spin, or redesign of the test logic.

There is a need in the art for a method and apparatus for accounting for testing de-featured memory without redesign of the MBIST logic.

### SUMMARY

Embodiments described herein provide a method for testing a device memory. The method begins with determining a generated data width generated by an automatic testing system, such as a MBIST system. A generated address width is also determined for the MBIST system. The generated data width and the generated address width is compared with the required data width and address width of a device under test. A user bit is set based on the comparison. If the generated data width and the generated address width match the required data width and the generated address width then the memory is not a de-featured memory, and the user bit is set to zero. If the generated data width and the generated address width do not match the required data width and the required address width, then the memory is a de-featured memory and the user bit is set to 1. The user bit setting cues the glue logic to provide address control and data control during the device.

An additional embodiment provides an apparatus for testing a device memory. The apparatus includes a wireless test access protocol that is electrically connected to a glue logic module. A test interface or MBIST is electrically connected to the glue logic module. A memory to be tested is electrically connected to the glue logic module.

A further embodiment provides an apparatus for testing a device memory. The apparatus comprises: means for determining a generated data width; means for determining a generated address width; means for comparing the generated data width and the generated address width with a device under test required data width and a device under test required address width; means for setting a user bit based on the comparison; and means for testing the device memory based on the user bit setting.

### BRIEF DESCRIPTION OF THE DRAWINGS

FIG. 1 is a block diagram of a typical SoC, in accordance with embodiments disclosed herein.

FIG. 2 is a chart of the address and data widths used by MBIST interfaces, in accordance with embodiments disclosed herein.

FIG. 3 illustrates testing a memory of a fixed configuration, in accordance with embodiments described herein.

FIG. 4 depicts testing a de-featured memory in accordance with embodiments described herein.

FIG. 5 shows an intelligent de-feature MBIST architecture (IDMA) for use with de-featured memories, in accordance with embodiments described herein.

FIG. 6 illustrates an intelligent de-featured MBIST architecture with de-featuring turned on, in accordance with embodiments described herein.

FIG. 7 is a schematic diagram of the IDMA glue logic, in accordance with embodiments described herein.

FIG. 8 is a schematic diagram of the IDMA glue logic handling multiple levels of memory de-featuring, in accordance with embodiments described herein.

FIG. 9 is a flowchart of using an IDMA to test a de-featured memory in accordance with embodiments described herein.

FIG. 10 is a flowchart of a further embodiment of using an IDMA to test a de-featured memory in accordance with embodiments described herein.

### DETAILED DESCRIPTION

Various aspects are now described with reference to the drawings. In the following description, for purposes of explanation, numerous specific details are set forth in order to provide a thorough understanding of one or more aspects. It may be evident, however, that such aspect(s) may be practiced without these specific details.

As used in this application, the terms “component,” “module,” “system” and the like are intended to include a computer-related entity, such as, but not limited to hardware, firmware, a combination of hardware and software, software, or software in execution. For example, a component may be, but is not limited to being, a process running on a processor, a processor, an object, an executable, a thread of execution, a program and/or a computer. By way of illustration, both an application running on a computing device and the computing device can be a component. One or more components can reside within a process and/or thread of execution and a component may be localized on one computer and/or distributed between two or more computers. In addition, these components can execute from various computer readable media having various data structures stored thereon. The components may communicate by way of local and/or remote processes such as in accordance with a signal having one or more data packets, such as data from one component interacting with another component in a local system, distributed system, and/or across a network such as the Internet with other systems by way of the signal.

As used herein, the term “determining” encompasses a wide variety of actions and therefore, “determining” can include calculating, computing, processing, deriving, investigating, looking up (e.g., looking up in a table, a database or another data structure), ascertaining and the like. Also, “determining” can include resolving, selecting choosing, establishing, and the like.

The phrase “based on” does not mean “based only on,” unless expressly specified otherwise. In other words, the phrase “based on” describes both “based only on” and “based at least on.”

Moreover, the term “or” is intended to man an inclusive “or” rather than an exclusive “or.” That is, unless specified otherwise, or clear from the context, the phrase “X employs A or B” is intended to mean any of the natural inclusive permutations. That is, the phrase “X employs A or B” is satisfied by any of the following instances: X employs A; X employs B; or X employs both A and B. In addition, the articles “a” and “an” as used in this application and the appended claims should generally be construed to mean “one or more” unless specified otherwise or clear from the context to be directed to a singular form.

The various illustrative logical blocks, modules, and circuits described in connection with the present disclosure may be implemented or performed with a general purpose processor, a digital signal processor (DSP), an application specific integrated circuit (ASIC), a field programmable gate array (FPGA), or other programmable logic device, discrete gate or transistor logic, discrete hardware components or any combination thereof designed to perform the functions described herein. A general purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core or any other such configuration.

The steps of a method or algorithm described in connection with the present disclosure may be embodied directly in hardware, in a software module executed by a processor or in a combination of the two. A software module may reside in any form of storage medium that is known in the art. Some examples of storage media that may be used include RAM memory, flash memory, ROM memory, EPROM memory, EEPROM memory, registers, a hard disk, a removable disk, a CD-ROM, and so forth. A software module may comprise a single instruction, or many instructions, and may be distributed over several different code segments, among different programs and across multiple storage media. A storage medium may be coupled to a processor such that the processor can read information from, and write information to, the storage medium. In the alternative, the storage medium may be integral to the processor.

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

The functions described may be implemented in hardware, software, firmware, or any combination thereof. If implemented in software, the functions may be stored as one or more instructions on a computer-readable medium. A computer-readable medium may be any available medium that can be accessed by a computer. By way of example, and not limitation, a computer-readable medium may comprise RAM, ROM, EEPROM, CD-ROM or other optical disk storage, magnetic disk storage, or other magnetic storage devices, or any other medium that can be used to carry or store desired program code in the form of instructions or data structures and that can be accessed by a computer. Disk and disc, as used herein, includes compact disk (CD), laser disk, optical disc, digital versatile disk (DVD), floppy disk, and Blu-ray® disc where disks usually reproduce data magnetically, while discs reproduce data optically with lasers.

Software or instructions may also be transmitted over a transmission medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of transmission medium.

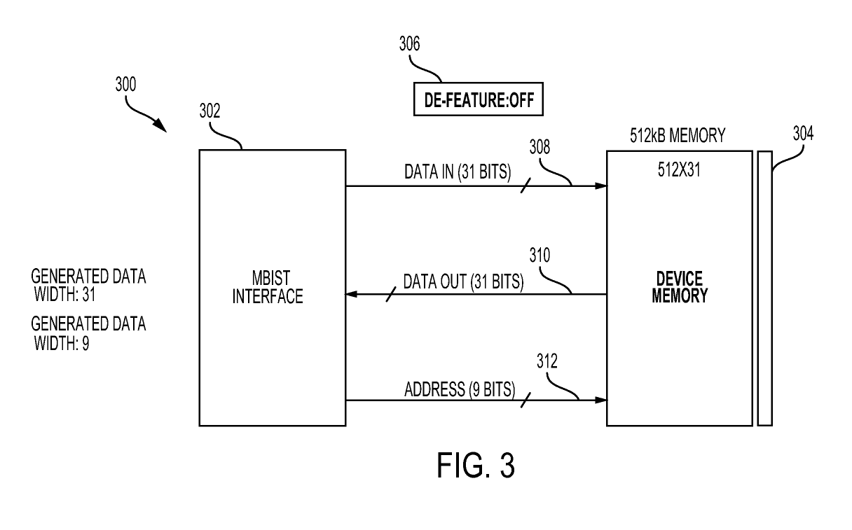

Further, it should be appreciated that modules and/or other appropriate means for performing the methods and techniques described herein, such as those illustrated by FIGS. 3-10, can be downloaded and/or otherwise obtained by a mobile device and/or base station as applicable. For example, such a device can be coupled to a server to facilitate the transfer of means for performing the methods described herein. Alternatively, various methods described herein can be provided via a storage means (e.g., random access memory (RAM), read only memory (ROM), a physical storage medium such as a compact disc (CD) or floppy disk, etc.), such that a mobile device and/or base station can obtain the various methods upon coupling or providing the storage means to the device. Moreover, any other suitable technique for providing the methods and techniques described herein to a device can be utilized.

Embodiments described herein relate to an architecture for testing SoC memories that may have been reduced in capacity by an operation known as memory de-featuring. Memory de-featuring reduces memory size by blowing a fuse. As an example, a cache memory may be reduced from 1 MB to 512 kB on the fly during the manufacturing process. This allows for adaptation to a particular customer's needs and requirements with the time and expense of redesign and fabrication.

A SoC is an integrated circuit that combines all components of a computer or other electronic system on a single chip. It may contain digital, analog, mixed-signal, and radio frequency (RF) functions. A typical SoC consists of: a microcontroller or digital signal processor (DSP) core; memory blocks, including a selection of read-only memory (ROM), random access memory (RAM), electrically erasable programmable read-only memory (a type of non-volatile memory), and flash memory; timing sources including oscillators and phase-locked loops (PLL); peripherals including counter-timers, real-time timers, and power-on or reset generators; external interfaces; analog interfaces including analog to digital converters (ADC), digital to analog converters (DAC); voltage regulators; and power management circuits. A bus connects these blocks within the SoC.

Direct memory access (DMA) controllers route data directly between external interfaces and memory, bypassing the processor core, thus increasing data throughput. DMA controllers are used because they allow certain hardware systems to access the main system memory (RAM) independently of the CPU and as a result improve data processing speed.

Many SoCs incorporate an Acorn Risc Machine (ARM) proprietary process into their architecture. A reduced instruction set computing (RISC) device may be used as a building block within a larger and more complex device, such as a SoC. The ARM processors may be configured for various environments. A RISC based design means that ARM processors require significantly fewer transistors than a complex instruction set computing (CISC) device, such as those found in most personal computers. This approach results in lower cost, less heat production, and less power consumed. As a result, ARM processors are used extensively in portable devices such as wireless devices and tablet, as well as in embedded systems. ARM processors use a simpler design with more efficient multi-core central processing units (CPU).

Typically, an ARM processor core supports a 32-bit address space and uses 32-bit arithmetic. Instructions for ARM cores often use 32-bit wide fixed length instructions, however, some versions support a variable length instruction set that uses 32-bit and 16-bit wide instruction sets for improved code density. In many cases an SoC will use the standard ARM processor core and will use a 32-bit address space and 32-bit arithmetic. However, some SoCs allow for a reduction in memory size by blowing a fuse. This process of reducing memory size by blowing a fuse is known as de-featuring. As an example, in one SoC core, the cache may be reduced from 1 MB to 512 KB during the manufacturing process. This allows a simple memory size reduction without the time and expense of a redesign.

Testing the SoCs is an important part of the manufacturing process. Built in self-test (BIST) and memory built in self-test (MBIST) are frequently used to test embedded memories within SoCs. MBIST testing provides a mechanism that allows a memory to test itself In addition, MBIST may be used to ensure high reliability and reduce repair cycle times. A general BIST architecture provides a test generator that interfaces with the circuit under test. the circuit under test receives input from the test generator and outputs a response verification. A test controller is connected to the test generator and also to a response verification device. The test controller generates control signals for the test pattern. These control signals are provided to the test pattern generator and the memory under test. The test pattern generator generates the required test patterns and the Read/Write signals. The comparator evaluates the response of the memory to the test signals.

Current MBIST architecture has three main components: a test access port (TAP), a controller, and an interface. MIST testing may also use analysis and testing tools that provide specific test functionality. These test tools may be developed to run on the same software platform as design tools and may incorporate proprietary testing operations and functions. In many situations the MBIST software tools rely on the common architecture supported by the computer-aided design tool. As a result, the MBIST logic is programmed to expect certain configuration settings. These configuration settings may be changed when a SoC has a de-featured memory. When this occurs, the installed MBIST logic software tools are not compatible with the de-featured memory. When the memory in a design undergoes changes in its configuration, the MBIST logic will also need to be redesigned from register transfer level insertion (RTL), synthesis and routing in order to be compatible with the new changes.

RTL is a design abstraction which models a synchronous digital circuit in terms of the flow of digital signals between hardware registers and logical operations performed on those signals. RTL abstraction may be used in hardware design description languages, such as Verilog, and VHDL to create high level representations of a circuit, from which lower-level representations and ultimately actual wiring can be derived. RTL focuses on describing the flow of signals between registers.

RTL is used in the logic design phase of the SoC design cycle. An RTL description is usually converted to a gate-level description of the circuit by a logic synthesis tool. The synthesis results are then used by placement and routing tools to create a physical layout. Logic simulation tools may use a design's RTL description to verify its correctness. When the RTL logic insertion must be re-done during a redesign, the MBIST logic testing flow must also be redesigned, significantly increasing costs. The configuration of the MBIST logic should be in accordance with the memory configuration for the test to be successful.

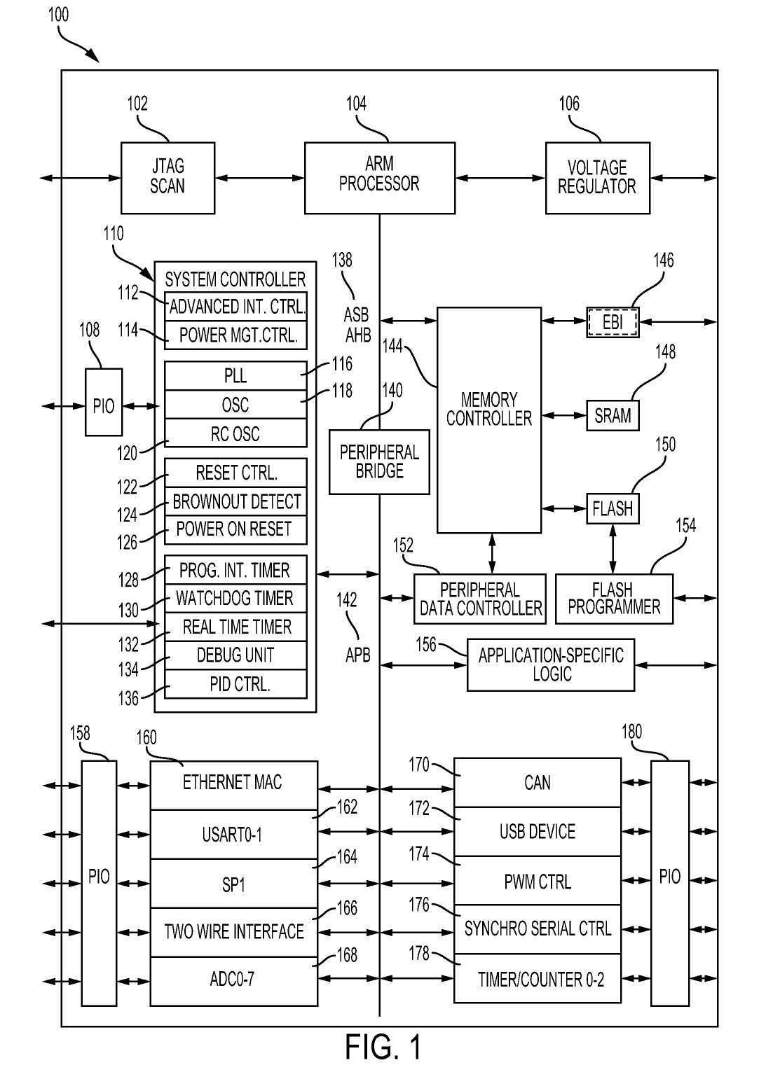

FIG. 1 illustrates a typical SoC, 100. The assembly 100 includes joint test action group (JTAG) scan device 102 which receives input signals for scanning. These signals are scanned before being sent to the ARM processor 104. The ARM processor 104 may also send input to JTAG scan device 102, which in turn may provide output. The ARM processor also interfaces with voltage regulator 106. The SoC 100 may also incorporate a first peripheral input/output interface (PIO) 108. This PIO 108 interfaces with a system controller 110. System controller 110 may incorporate an advanced interface controller 112, a power management controller 114, a phase locked loop (PLL) 116, an oscillator 118, a resistor-capacitor (RC) oscillator 120, a reset controller 122, a brownout detector 124, a power on reset device 126, a program interrupt timer 128, a watchdog timer 130, a real time timer 132, a debug unit 134, and a proportional/integral/derivative (PID) controller 136. All of the devices under the control of system controller 110 interface through the PIO.

The ARM processor 104 interfaces with peripheral bridge 140, which also provides input and output interface with the system controller 110. The peripheral bridge communicates with multiple components using an application peripheral bus (APB) 142. An internal bus 138 operates in conjunction with the peripheral bridge 140 to communicate with additional devices within the SoC 100. The internal bus 138 may be an application specific bus (ASP) or an application handling bus (AHB). Memory controller 140 interfaces with ARM processor 104 using internal bus 138. The memory controller 140 also communicates with the external bus interface (EBI) 146. Memory controller 140 is also in communication with static random access memory (SRAM) 148, and flash memory 150. Flash memory 150 is in communication with flash programmer 154. The memory controller 144 is also in communication with peripheral data controller 152. Additional application specific logic 156 communicates with the internal bus 138 and may also have external connections. A second PIO 158 provides communication with an Ethernet medium access control (MAC) 160. The second PIO 158 also communicates with a universal asynchronous receiver/transmitter 162, a serial peripheral interface (SPI) 164, a two wire interface 166, and an analog to digital converter 168. These devices and interfaces connect through internal bus 138 with controller area network bus (CAN) 170, a universal serial bus (USB) devices 172, a pulse width modulator (PWM) controller 174, a synchro serial controller 176, and a timer/counter 178. These devices, CAN 170, USB device 172, PWM controller 174, synchro serial controller 176 and timer/counter 178 interface with third PIO 180, which provides external input and output. While these elements are typical of many SoCs, other devices may be incorporated, and some may not be included.

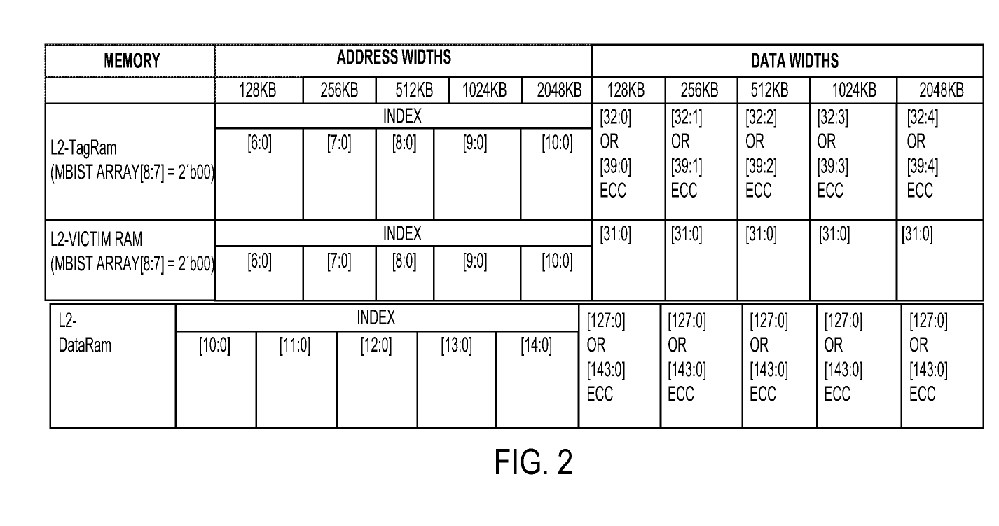

FIG. 2 illustrates the address and data widths found in a variety of SoC cores that incorporate an ARM processor, such as ARM processor 104 in FIG. 1. Depending on memory size, different address and data widths are specified. For every different type of core the ARM processor needs a particular addres width and data width for the size of the cache memory. FIG. 2 illustrates a cache configuration table for a representative core.

FIG. 3 illustrates testing a memory of a fixed configuration. The test flow 300 shows MBIST interface 302 having a generated data width of 31 and a generated address width of 9. De-feature option 306 is OFF. Data in test signals of 31 bits 308 are input to device memory 304. Device memory 304 is a 512 KB memory having a required data width of 31 and a required address width of 9. Device memory 304 outputs data out signals of 31 bits 310 to MBIST interface 302. A nine bit address 312 is also input to device memory 304. In the example of FIG. 3, nine bits of address and 31 bits of data are required to test the 512 KB memory 304. As there is a match between the generated and required data widths as well as the generated address and required address width, the MBIST test will pass. However, if there is any difference between the configuration of the actual memory and the MBIST logic, the test will fail.

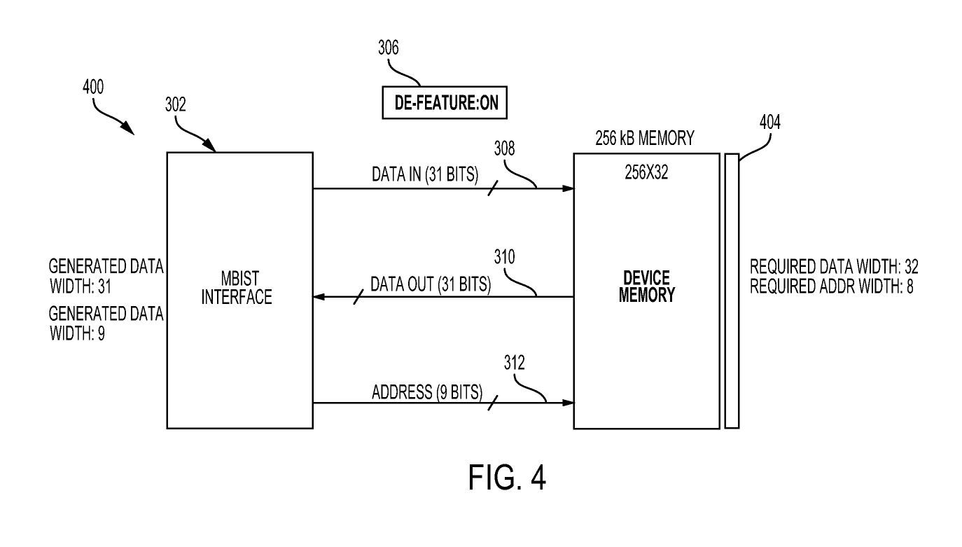

FIG. 4 depicts testing a de-featured memory. The test flow 400 shows MBIST interface 302 having a generated data width of 31 bits and a generated address width of 9 bits. De-feature operation 306 is ON. De-featured device memory 404 is a 256 KB memory with a required data width of 32 bits and a required address width of 8 bits. Data in test signals 308 are again sent from MBIST interface 302 to de-featured device memory 404. Data out 310 is sent from de-featured memory 404 to MBIST interface 302. MBIST interface 302 provides address input 312 to de-featured device memory 404. In this example, eight bits of address and 32 bits of data are required to test the de-featured memory. However, the MBIST interface 302 sends nine bits of address and 31 bits of data. This mismatch results in test failure.

This difficulty may be overcome using an intelligent de-feature MBIST architecture. This architecture provides the flexibility to reuse the existing MBIST logic to test the de-featured memory and does not require any hardware changes. The architecture is in the form of a parameterized RTL and is capable of handling de-featuring by a number of levels. By 2 de-featuring takes a 2 MB memory and reduces it to a 1 MB memory. Similarly, by 4 de-featuring starts with a 2 MB memory and ends with a 512 KB memory. By 8 de-featuring starts with a 2 MB memory and ends with a 256 KB memory. By 16 de-featuring starts with a 2 MB memory and ends with a 128 KB memory.

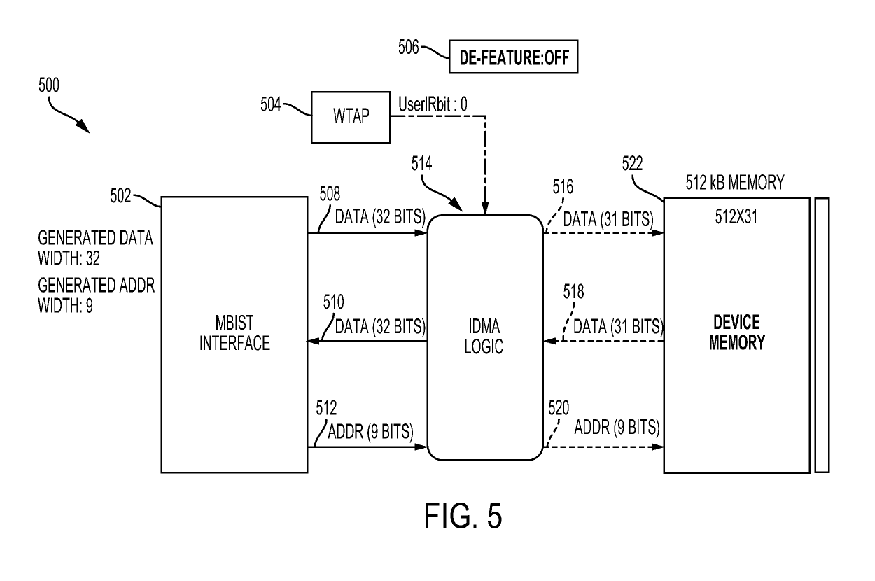

FIG. 5 is a block diagram of an embodiment of an architecture for intelligent de-featuring when the de-featuring is turned off The assembly 500 includes MBIST interface 502. A wireless test access port (WTAP) 504 provides input to the intelligent de-feature memory BIST architecture (IDMA) logic 514. The MBIST interface provides 32 bits of data input 508 to IDMA logic 514. The MBIST interface also provides 9 bits of address 512 to IDMA logic 514. The IDMA logic outputs 31 bits of data 516 to the device memory 522. Device memory 522 is a 512 KB memory. IDMA logic 514 also receives 31 bits of data from device memory 522, and passes this data to the MBIST interface 502. The IDMA logic 514 also provides 9 bits of address 520 to device memory 522. IDMA logic 514 provides 32 bits of data 510 to MBIST interface 502. In this example de-featuring 506 is off and the programmable UserIRbit is set to 0. MBIST interface 502 has a generated data width of 32 bits and a generated address width of 9 bits, while device memory 522 has a required data width of 31 bits and a required address width of 9.

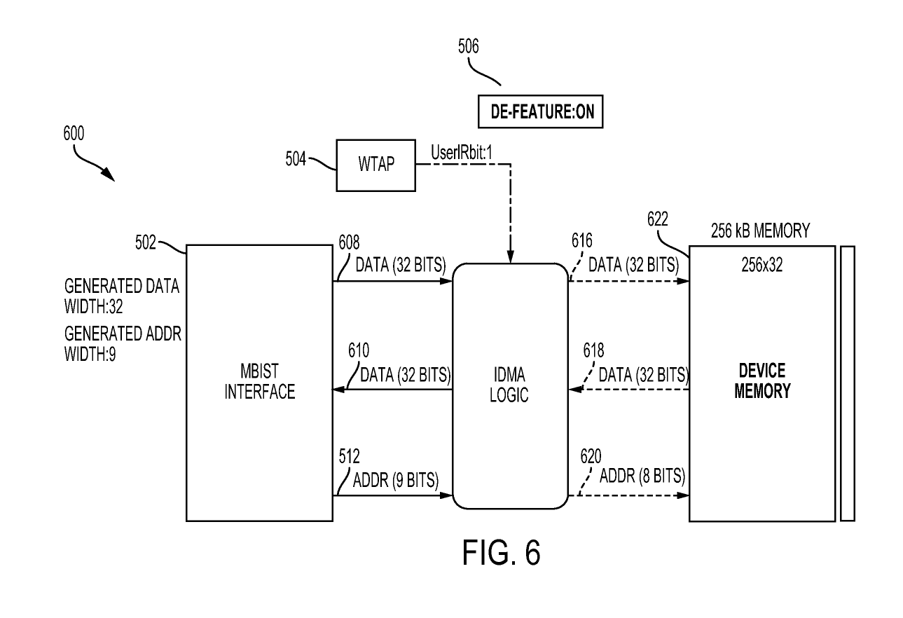

FIG. 6 is a block diagram of an embodiment of an architecture for intelligent de-featuring when the de-featuring is turned on. The assembly 600 includes MBIST interface 502. A wireless test access port 504 provides input to the IDMA logic 514. The MBIST interface provides 32 bits of data input 508 to IDMA logic 514 and 9 bits of address 512 to IDMA logic 514. The IDMA logic 514 forwards 32 bits of data 616 to the de-featured memory 622 and also provides 8 bits of address 620 to the de-featured memory 622. The de-featured memory 622 returns 32 bits of data 618 to IDMA logic 514, which then passes the 32 bits of data 610 to the MBIST interface 502.

The glue logic contained in IDMA logic 514 modifies the 9 bit address 512 coming from the MBIST interface 502 to match the de-featured configuration of memory 622 and any associated RAM memories. This configuration requires that the UserIR bit used in WTAP 504 be set to 1.

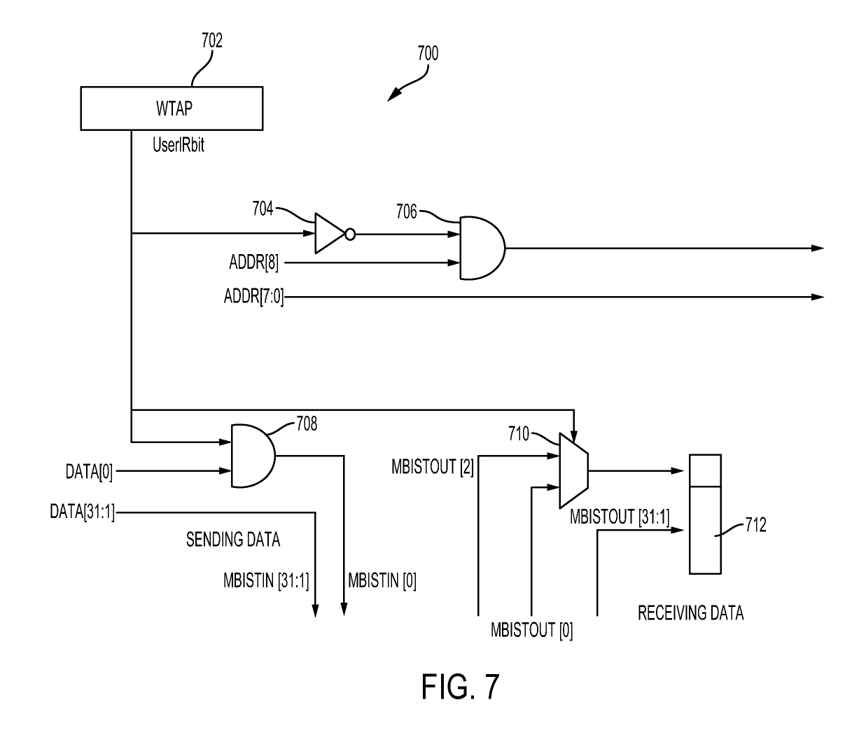

FIG. 7 is a schematic diagram of the IDMA glue logic according to an embodiment. The assembly 700 includes WTAP 702. The WTAP 702 sends UserIRbit to both address and data control functions. Address control is used to control the most significant bit (MSB) of the address. This address control uses first AND gate 706. The UserIRbit is first sent to inverter 704, which passes the information to first AND gate 706. In operation the WTAP logic low is applied to inverter 704, causing the output to be inverted to a logic high. This logic high from the inverter 704 is applied to an input of first AND gate 706. This allows Addr[8] bit applied to AND gate 706 input to pass through the first AND gate 706. This operation allows the Addr[8] input bit to output to address the upper half of the memory under test.

If WTAP 702 UserIRbit is high then it is applied to inverter 704, which drives the output of inverter 704 to a logic low, which is then applied to first AND gate 706 input. Addr[8] bit is applied to the other input of AND gate 706. The output of first AND gate 706 remains low, and addresses only the lower half of the memory under test.

If WTAP 702 UserIRbit is high then it is applied to second AND gate 708. Data bit [0] is applied to the other input of second AND gate 708, allowing the data bit to pass through second AND gate 708. Data control in the IDMA glue logic is based on the fact that every alternate data bit generated and expected by the interface is the same for all algorithms.

With WTAP 702 UserIRbit at logic low and applied to second AND gate 708 as an input, Data[0] is applied to second AND gate 708 on the second input. This blocks Data[0] from passing to the output of second AND gate 708.

When WTAP 702 UserIRbit is at logic low and is applied to multiplexer 710, then MBISTout[0] is applied to the output of multiplexer 710. In contrast, when WTAP UserIRbit is at logic high and is applied to multiplexer 710, the MBISTout[2] is applied to the output of mulitplxer 710.

The output of multiplexer 710 and MBISTout[31:1] are input to fixed input comparator 712. Fixed input comparator 712 is a 32-bit comparator and is used to check data. Fixed input comparator 712 expects every alternate data bit to be the same. However, bit 0 may cause problems. The multiplexer 710 lets MBISTout[0] go to the fixed input comparator 712. This prevents comparator failure when bit 0 is encountered. Other implementations may use different data and comparator sizes and still be within the scope of the description herein. FIG. 7 illustrates by 2 de-featuring. Handling by 16 or by 8 de-featuring requires adding additional multiplexers to control the data width.

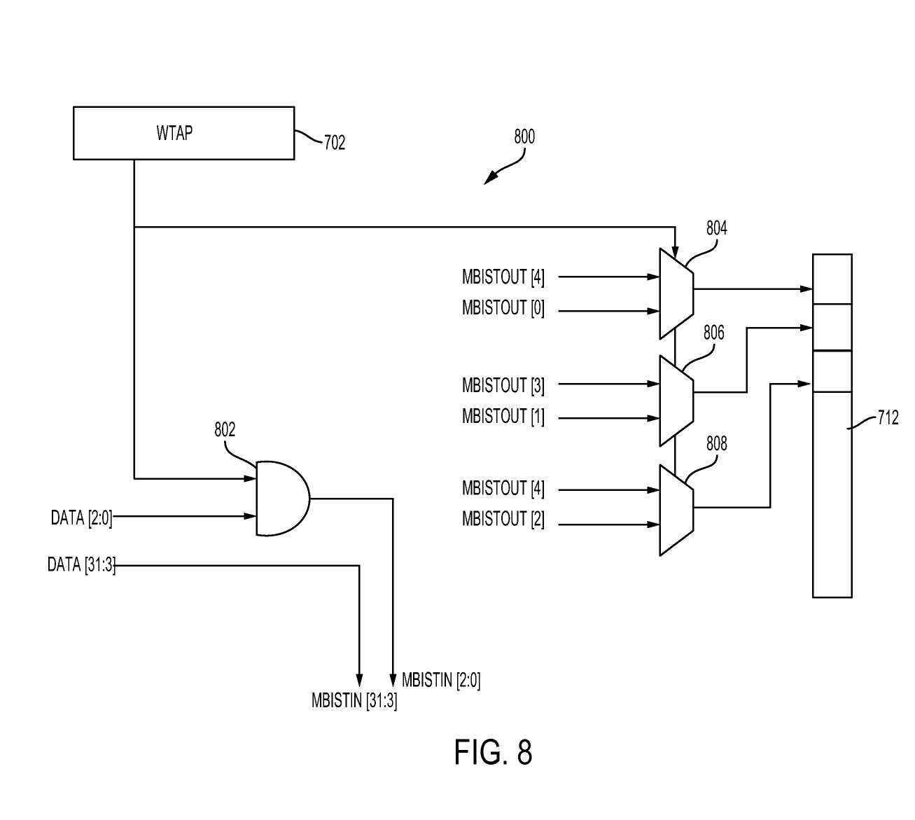

FIG. 8 is a schematic diagram of the IDMA glue logic handling multiple levels of memory de-featuring according to a further embodiment. In operation the by 16 and by 8 de-featuring operates as described above for address and data control with respect to inverter 704 and first AND gate 706. However, FIG. 8 describes the details of processing where additional multiplexers in place of multiplexer 710 in FIG. 7 are used. FIG. 8 provides an assembly 800 that incorporates first multiplexer 804, second multiplexer 806, and third multiplexer 808. These additional multiplexers are needed to control data width for higher levels of de-featuring. The first multiplexer 804 lets MBISTout[4] go to the fixed input comparator 712. This prevents comparator failure when bit 0 is encountered. Second multiplexer 806 allows MBISTout[1] to pass to fixed input comparator 712. Third multiplexer 808 allows MBISTout[2] to pass to fixed input comparator 712. Second AND gate 708 operates as described above with respect to FIG. 7.

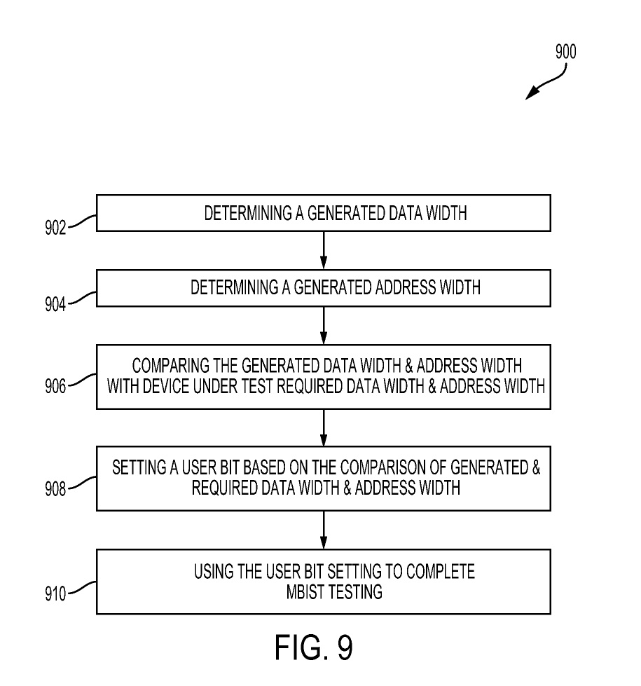

FIG. 9 is a flowchart of using an IDMA to test a de-featured memory. The method 900 begins with the MBIST interface determining a generated data width in step 902 and a generated address width in step 904. The fixed 32 bit comparator then compares the generated data width and the generated address width with the device under test required data width and required address width in step 906. Then, in step 908 a user bit is set based on the comparison. The user bit is set to match the width of the device under test bus width, specifically data width and address width. The IDMA logic sets the user bit. If the generated data width and generated address width are the same, the user bit is set to 0, indicating that de-featuring is off In step 910 the user bit setting is used to conduct MBIST testing of the device memory.

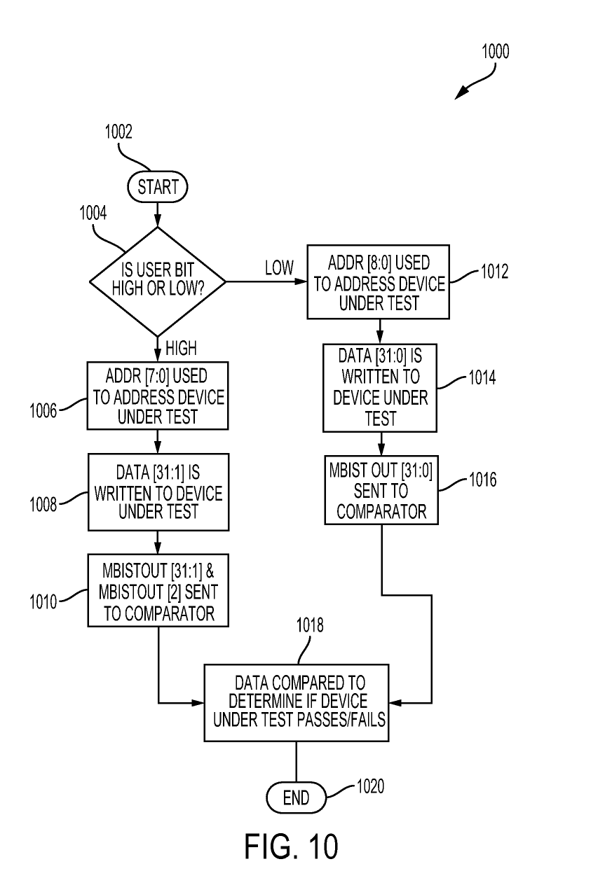

FIG. 10 is a flowchart of the operation of the IDMA glue logic. The method 1000, begins at start 1002. In decision block 1004 the question is posed “Is the user bit high or low?” If the user bit is high, then in step 1006 ADDR [7:0] is used to address the device under test. In step 1008, DATA [31:1] is then written to the device under test. In step 1010 MBISTOUT [31:1] and MBISTOUT [2] are sent to the fixed 32 bit comparator. If the user bit is low, then in step 1012 ADDR [8:0] is used to address the device under test. In step 104 DATA [31:0] is written to the device under test. In step 1016 MBISTOUT [31:0] is sent to the fixed 32 bit comparator. For both the high and low user bit values, once the MBISTOUT value is sent to the comparator, the comparison is made in step 1018 and it is determined if the device under test passes or fails. At step 1020, the process ends.

It is understood that the specific order or hierarchy of steps in the processes disclosed is an illustration of exemplary approaches. Based upon design preferences, it is understood that the specific order or hierarchy of steps in the processes may be rearranged. The accompanying method claims present elements of the various steps in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” Unless specifically stated otherwise, the term “some” refers to one or more. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed as a means plus function unless the element is expressly recited using the phrase “means for.”

It is to be understood that the claims are not limited to the precise configuration and components illustrated above. Various modifications, changes and variations may be made in the arrangement, operation and details of the systems, methods, and apparatus described herein without departing from the scope of the claims.

What is claimed is:

1. A method for testing a device memory, comprising:
determining a generated data width;
determining a generated address width;
comparing the generated data width and the generated address width with a device under test required data width and a device under test required address width;
setting a user bit based on the comparison; and
testing the device memory based on the user bit setting.

2. The method of claim 1, wherein the user bit is set to zero if the generated data width and the generated address width match the required data width and the required address width of the device under test.

3. The method of claim 1, further comprising:
forwarding test instructions from a test interface to a glue logic module based on the user bit setting before testing the device memory based on the user bit setting.

4. The method of claim 1, wherein the user bit is set to one if the generated data width and the generated address width do not match the required data width and the required address width of the device under test.

5. The method of claim 1, wherein the glue logic adjusts the generated data width and the generated address width to match the required data width and the required address width of a device under test.

6. The method of claim 5, wherein the user bit provides address width control by controlling the most significant bit of an address.

7. An apparatus for testing a device memory, comprising:
a wireless test access protocol electrically connected to a glue logic module;
a test interface electrically connected to the glue logic module; and
and a de-featured memory electrically connected to the glue logic module.

8. The apparatus of claim 7, wherein the glue logic module comprises:
an inverter connected to a wireless test access protocol;
a first AND gate electrically connected to the inverter;
a second AND gate electrically connected to the wireless test access protocol; and
at least one multiplexer electrically connected to the wireless test access protocol.

9. The apparatus of claim 8, wherein the at least one multiplexer comprises one multiplexer.

10. The apparatus of claim 8, wherein the at least one multiplexer comprises three multiplexers connected in series.

11. An apparatus for testing a device memory, comprising:
means for determining a generated data width;
means for determining a generated address width;
means for comparing the generated data width and the generated address width with a device under test required data width and a device under test required address width;
means for setting a user bit based on the comparison; and
means for testing the device memory based on the user bit setting.

12. The apparatus of claim 11, wherein the means for setting a user bit based on the comparison sets the user bit to zero if the generated data width and the generated address width match the required data width and the required address width of the device under test.

13. The apparatus of claim 11, further comprising:
means for forwarding test instructions from a test interface to a glue logic module based on the user bit setting.

14. The apparatus of claim 11, wherein the means for setting a user bit sets the user bit to one if the generated data width and the generated address width do not match the required data width and the required address width of the device under test.

15. The apparatus of claim 11, further comprising: means for adjusting the generated data width and the generated address width to match the required data width and the required address width of a device under test.

16. The apparatus of claim 15, wherein the means for adjusting the generated data width and the generated address width controls the address width.

17. The apparatus of claim 8, wherein the generated address width is controlled using a most significant bit of the address width.

18. The method of claim 1, wherein the setting of the user bit determines the address used to address the device under test.

19. The method of claim 1, wherein the setting of the user bit determines the data that is written to the device under test.
